(19) United States
(12) Patent Application Publication
(10) Pub. No.: US 2023/0402260 A1
(43) Pub. Date: Dec. 14, 2023

(54) GAS ABATEMENT BY PLASMA

(71) Applicant: Edwards Limited, Burgess Hill, Sussex (GB)

(72) Inventors: Simone Magni, Burgess Hill, Sussex (GB); Neil Condon, Burgess Hill, Sussex (GB); Erik Wagenaars, Burgess Hill, Sussex (GB)

(21) Appl. No.: 18/250,653

(22) PCT Filed: Nov. 1, 2021
(86) PCT No.: PCT/GB2021/052820

§ 371 Date: Apr. 26, 2023

(30) Foreign Application Priority Data
Nov. 2, 2020 (GB) 2017320.9

(51) Int. Cl. H01J 37/32

(52) U.S. Cl. CPC H01J 37/32449; H01J 37/32844; H01J 37/32458; H01J 2237/327

(57) ABSTRACT

A plasma abatement apparatus includes: a plasma device configured to generate a plasma stream from a plasma gas; an effluent stream aperture configured to convey the effluent stream into the plasma stream for treatment by the plasma stream; a first aperture positioned to deliver a reducing reactant to a first region of the plasma stream; and a second aperture positioned to deliver an oxidising reactant to a second region of the plasma stream, wherein the second region is located at a position of the plasma stream which is cooler than the first region.

### FIELD OF THE INVENTION

The field of the invention relates to plasma abatement. Embodiments relate to an apparatus and method for treating an effluent stream from a semiconductor processing tool.

### BACKGROUND

Plasma abatement apparatus are known and are typically used for, amongst other things, treating an effluent gas stream from a manufacturing process tool used in, for example, the semiconductor or flat panel display manufacturing industry. During such manufacturing, residual fluorinated or perfluorinated compounds (PFCs) and other compounds exist in the effluent gas stream pumped from the process tool. These compounds are difficult to remove from the effluent gas stream and their release into the environment is undesirable because they are known to have relatively high greenhouse activity.

One approach to remove the PFCs and other compounds from the effluent gas stream is to use a radiant burner as described, for example, in EP1773474. However, when fuel gases normally used for abatement by combustion are undesirable or not readily available, it is also known to use a plasma abatement device.

Although these apparatus exist for processing the effluent gas stream, they each have their own shortcomings. Accordingly, it is desired to provide an improved technique for processing and effluent gas stream.

### SUMMARY

According to a first aspect, there is provided a plasma abatement apparatus for treating an effluent stream from a semiconductor processing tool, the plasma abatement apparatus comprising: a plasma device configured to generate a plasma stream from a plasma gas; an effluent stream aperture configured to convey the effluent stream into the plasma stream for treatment by the plasma stream; a first aperture positioned to deliver a reducing reactant to a first region of the plasma stream; and a second aperture positioned to deliver an oxidising reactant to a second region of the plasma stream, wherein the second region is located at a position of the plasma stream which is cooler than the first region.

The first aspect recognizes that a problem with existing plasma abatement apparatus arrangements is that their abatement effectiveness can be lower than required and unwanted by-products can be produced in undesirable quantities. Accordingly, an apparatus is provided. The apparatus may be a plasma abatement apparatus. The apparatus may treat or abate an effluent stream from a semiconductor processing tool. The apparatus may comprise a plasma device or generator which generates a plasma stream from a plasma gas. The apparatus may comprise an effluent stream aperture or opening which conveys the effluent stream into the plasma stream. The effluent stream may then be treated by the plasma stream. The apparatus may comprise a first aperture or opening which delivers a reducing reactant into a first location, region or zone of the plasma stream. That first aperture may be the same aperture that delivers the plasma gas to the plasma device and from which the plasma is generated. The apparatus may comprise a second aperture or opening which is positioned to deliver an oxidizing reactant to a second location, region or zone of the plasma stream. The second region may be located to deliver the oxidizing reactant to a position within the plasma stream which is cooler than the position where the reducing reactant is delivered. In this way, the reducing reagent is introduced into a hotter or more active region of the plasma stream and the oxidizing reagent is introduced into a cooler or less active region of the plasma stream. This enables the reducing reaction to be more effective since the reducing reactant is present in the hotter region and the absence of the oxidizing reactant in this hotter region reduces the presence of thermally created undesirable oxides. Similarly, the introduction of the oxidizing reactant helps to remove by-products generated by the reducing reaction, and because the oxidizing reactant is introduced into the cooler region of the plasma stream, the amount of undesirable thermally generated oxides is reduced.

The first region may be located at a position of the plasma stream which is hotter than the second region.

The first region may be located at a position within the plasma stream which achieves a temperature of 1000° C. or more.

The second region may be located at a position within the plasma stream which achieves a temperature of no more than or less than 1000° C.

The second region may be located at a position within the plasma stream which achieves a temperature of 500° C. or more.

The second region may be located downstream of the first region.

The first region may be located upstream of the second region.

The reducing reactant may be pre-mixed with the plasma gas prior to the combined reactant and plasma gas being delivered to the plasma device.

The first region may be located proximate or near to the plasma device.

The second region may be located distal or away from the plasma device.

The apparatus may comprise a reaction chamber which is positioned to receive the plasma stream and the second region may be located within the reaction chamber.

The reducing reactant may comprise H₂.

The apparatus may comprise a hydrogen generator configured to generate the H₂ in situ by electrolysis.

The apparatus may comprise a power generator employed to generate the plasma stream or a secondary power source configured to power the hydrogen generator.

The reducing the reactant may comprise NH₃.

The first aperture may be configured to deliver an ammonia salt such as ammonium carbonate (NH₄)2CO₃, or the like to generate the NH₃ by thermal decomposition within the first region.

The apparatus may comprise a heater configured to generate the NH₃ by thermal decomposition of an ammonia salt such as ammonium carbonate (NH₄)2CO₃, or the like.

The reducing reactant may comprise a hydrocarbon (CₓH_{y}) such as propane, methane and the like.

The reducing reactant may comprise an alkaline earth metal such as beryllium, magnesium, calcium, strontium, and/or barium.

The reducing reactant may comprise an alkaline earth salt.

The reducing reactant may comprise an alkaline metal such as lithium, sodium, potassium, rubidium.

The reducing reactant may comprise an alkaline salt.

The oxidizing reactant may comprise O₂.

The oxidizing reactant may comprise O₃.

According to a second aspect, there is provided a method of treating an effluent stream from a semiconductor processing tool, comprising: generating a plasma stream from a plasma gas; conveying the effluent stream into the plasma stream for treatment by the plasma stream; delivering a reducing reactant to a first region of the plasma stream; and delivering an oxidising reactant to a second region of the plasma stream which is located at a position of the plasma stream which is cooler than the first region.

The method may comprise locating the first region at a position of the plasma stream which is hotter than the second region.

The method may comprise locating the first region at a position of the plasma stream which achieves a temperature of at least 1000° C.

The method may comprise locating the second region at a position of the plasma stream which achieves a temperature of no more than 1000° C.

The method may comprise locating the second region at a position of the plasma stream which achieves a temperature of at least 500° C.

The method may comprise locating the second region downstream of the first region.

The method may comprise locating the first region upstream of the second region.

The method may comprise locating premixing the reducing reactant with the plasma gas prior to delivery to the plasma device.

The method may comprise locating the first region proximate the plasma device.

The method may comprise locating the second region distal the plasma device.

The method may comprise receiving the plasma stream in a reaction chamber and locating the second region within the reaction chamber.

The reducing reactant may comprise H₂.

The method may comprise generating the H₂ in situ by electrolysis.

The method may comprise generating the H₂ using a hydrogen generator powered by a power generator employed to generate the plasma stream or by a secondary power source.

The reducing the reactant may comprise NH₃.

The method may comprise generating the NH₃ by thermal decomposition of an ammonia salt such as ammonium carbonate (NH₄)2CO₃, or the like.

The reducing reactant may comprise a hydrocarbon (CₓH_{y}) such as propane, methane and the like.

The reducing reactant may comprise an alkaline earth metal such as beryllium, magnesium, calcium, strontium, and/or barium.

The reducing reactant may comprise an alkaline earth salt.

The reducing reactant may comprise an alkaline metal such as lithium, sodium, potassium, rubidium.

The reducing reactant may comprise an alkaline salt.

The oxidizing reactant may comprise O₂.

The oxidizing reactant may comprise O₃.

According to a third aspect, there is provided a plasma abatement apparatus for treating an effluent stream from a semiconductor processing tool, said plasma abatement apparatus comprising: a first aperture positioned to deliver a reducing reactant premixed with a plasma gas to a plasma device configured to generate a plasma stream having the reducing agent in a first region of the plasma stream; an effluent stream aperture configured to convey said effluent stream into said plasma stream for treatment by said plasma stream; and a second aperture positioned to deliver an oxidising reactant to a second region of said plasma stream, wherein said second region is located at a position of said plasma stream which is cooler than said first region.

The apparatus of the third aspect may have the optional features of the first aspect set out above.

According to a fourth aspect, there is provided a method of treating an effluent stream from a semiconductor processing tool, comprising: delivering a reducing reactant premixed with a plasma gas to a plasma device; generating a plasma stream having the reducing agent in a first region of the plasma stream; conveying said effluent stream into said plasma stream for treatment by said plasma stream; and delivering an oxidising reactant to a second region of said plasma stream which is located at a position of said plasma stream which is cooler than said first region.

The method of the fourth aspect may have the optional features of the second aspect set out above.

Further particular and preferred aspects are set out in the accompanying independent and dependent claims. Features of the dependent claims may be combined with features of the independent claims as appropriate, and in combinations other than those explicitly set out in the claims.

Where an apparatus feature is described as being operable to provide a function, it will be appreciated that this includes an apparatus feature which provides that function or which is adapted or configured to provide that function.

### BRIEF DESCRIPTION OF THE DRAWINGS

Embodiments of the present invention will now be described further, with reference to the accompanying drawings, in which:

FIG. 1 illustrates a DC plasma torch according to one embodiment;

FIG. 2 shows an arrangement similar to that of FIG. 1 but which utilizes an inductively coupled plasma torch;

FIG. 3 is similar to that shown in FIG. 1 but the reducing reactant is introduced inside or in close proximity to the cathode;

FIG. 4 shows an arrangement which is similar to that shown in FIG. 2 but with the reducing reagent being injected inside or in close proximity to the gas discharge of the insulated tube of the plasma torch; and

FIGS. 5A to 5E show abatement performance under different configurations.

### DESCRIPTION OF THE EMBODIMENTS

Before discussing the embodiments in any more detail, first an overview will be provided. Some embodiments provide an arrangement which improves the abatement efficiency of a plasma abatement apparatus. This is achieved by splitting the introduction of reactants into the plasma stream. In particular, a reducing reactant is delivered at a first position into the plasma stream and an oxidizing reactant is introduced at a second position in the plasma stream. The reducing reactant may be premixed with the plasma gas and so the first position may be the position where the plasma gas is first introduced or may be downstream of this position but upstream of the second position. This enables reducing reactants to be introduced at a higher temperature or more active region of the plasma stream and oxidizing reactants to be introduced at a lower temperature or less active region of the plasma stream. Introducing the oxidizing reactants at the lower temperature region of the plasma stream reduces the production of unwanted oxides while ensuring that the reduction of some compounds can still occur in the higher temperature region. Improved abatement performance is achieved with lower levels of unwanted by-products compared to introducing the reducing and oxidising reactants together.

Plasma Torch

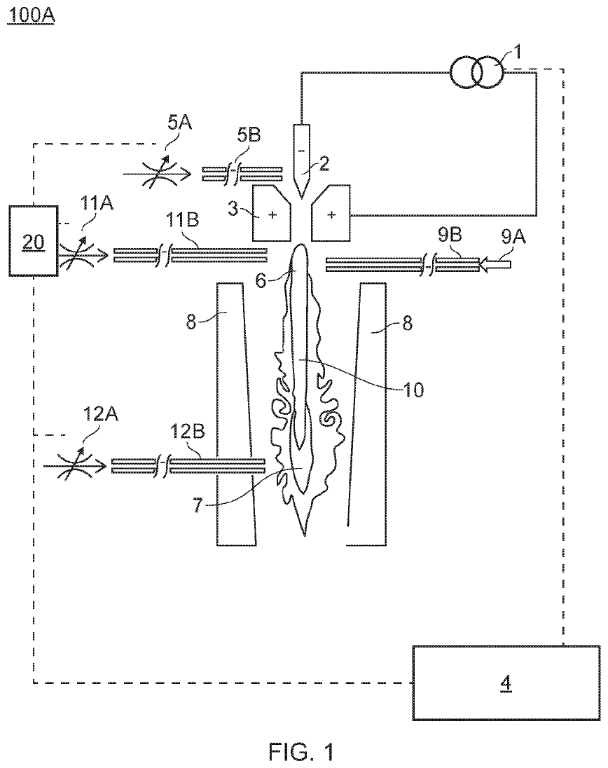

FIG. 1 illustrates a DC plasma torch 100A according to one embodiment. A nozzled anode 3 is co-located with a coaxial cathode 2. A constant direct current power supply 1 is electrically coupled with the cathode 2 and the anode 3. A plasma gas carrier conduit 5B is positioned to deliver a plasma gas carrier 5A into a void between the cathode 2 and the anode 3. Downstream of the anode 3 is located a reaction chamber 8. An effluent stream conduit 9B is positioned to deliver an effluent stream 9A to a position between the anode 3 and the reaction chamber 8. A reducing reactant conduit 11B is positioned to deliver a reducing reactant 11A to a position between the anode 3 and the reaction chamber 8. An oxidizing reactant conduit 12B is positioned in the wall of the reaction chamber 8 to deliver an oxidizing reactant 12A into the reaction chamber 8. A controller 4 is coupled with the power supply 1 and the source of the plasma gas carrier 5A, the source of the reducing reactant 11A and the source of the oxidizing reactant 12A.

In operation, the controller 4 switches the power supply 1 to create a voltage difference between the cathode 2 and the anode 3 to initiate the plasma. Once the plasma is created it drives a constant direct current (DC) between the cathode 2 and the anode 3 (the power supply 1 operates as constant current power supply). The controller 4 causes the plasma gas carrier 5A to be delivered via the plasma gas carrier conduit 5B which creates a plasma plume 10 through a DC arc discharge between the cathode 2 and the anode 3. The plasma plume 10 extends into the reaction chamber 8. The discharge is sustained by the injection of the plasma gas carrier 5A.

The effluent stream 9A is conveyed to the plasma plume 10 by the effluent stream conduit 9B. The abatement reaction then takes place inside the reaction chamber 8, which is typically cylindrical in shape and provides thermal insulation. Hence, the effluent stream 9A mixes with the plasma plume 10 within the reaction chamber 8.

To assist the abatement reaction, the controller 4 controls the introduction of the reducing reactant 11A through the reducing reactant conduit 11B. Thus, the reducing reactant 11A mixes with the effluent stream 9A in a hotter zone 6 of the plasma plume 10. Typically, the hotter zone 6 experiences a temperature in excess of 1000° C. Optionally, a generating device 20 under the control of the controller 4 generates the reducing reactant 11A (such as H₂ by electrolysis or NH₃ by thermal decomposition).

The controller 4 controls the introduction of the oxidizing reactant 12A via the oxidizing reactant conduit 12B into a cooler zone 7 of the plasma plume 10, which is downstream of the hotter zone 6. Typically, the cooler zone 7 experiences a temperature which is greater than around 500° C. but which is lower than 1000° C.

Performance

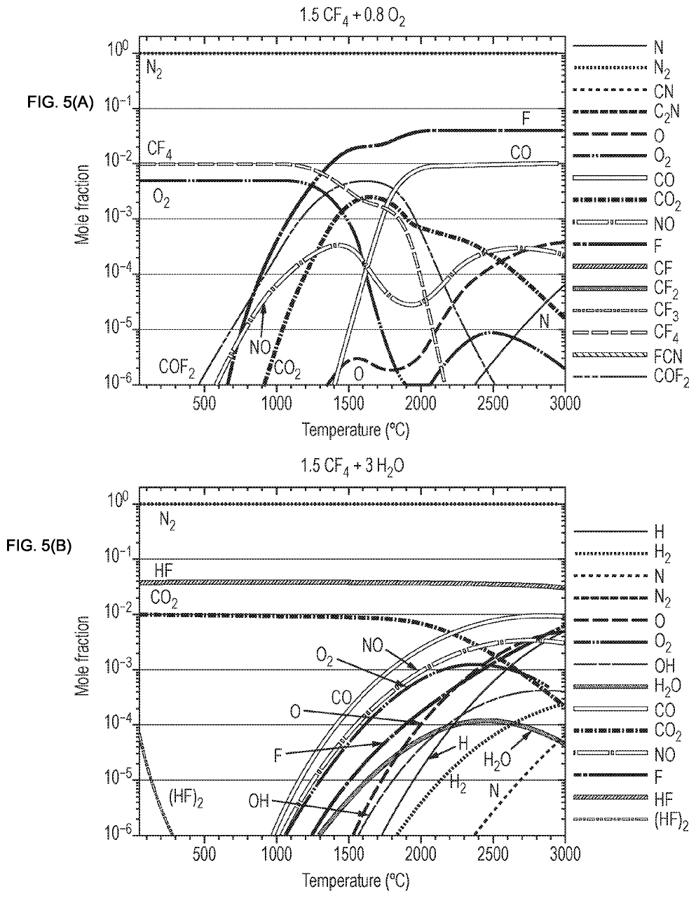

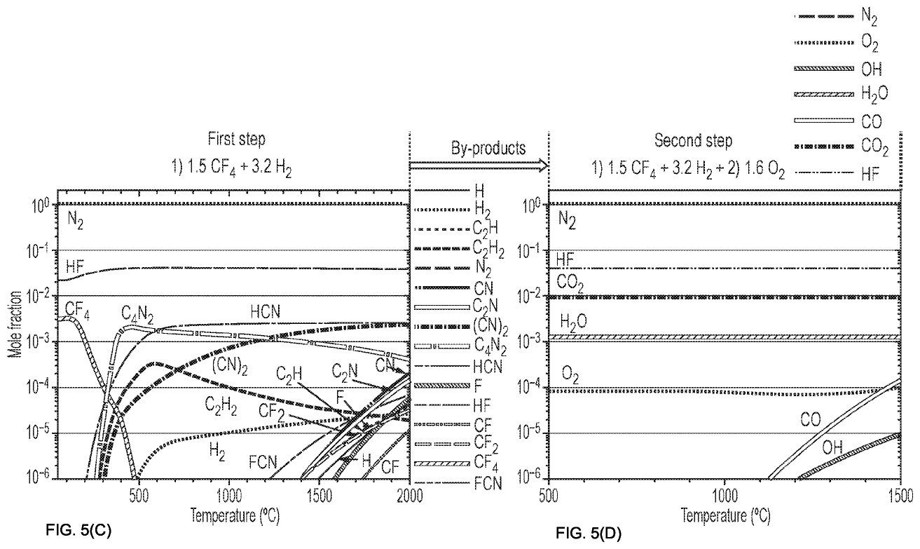

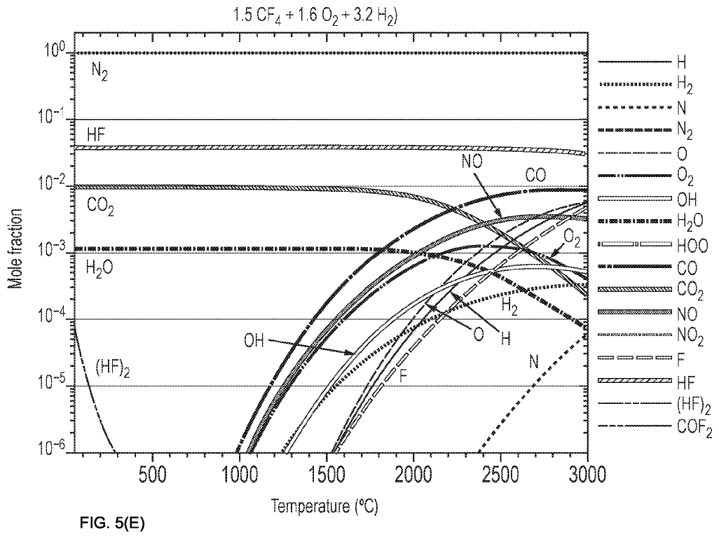

FIGS. 5A to 5E show abatement performance under different configurations. One of the main challenges for abatement by means of thermal plasma torch is to achieve high efficiency of the abatement process so that the torch power can be reduced to its lowest possible amount. This results in a lower cost of operation due to the lower electrical energy demand. Another challenge in abatement by means of thermal plasma torches is to reduce the level of unwanted NOx emissions. Additionally, oxygen can act as an inhibitor of the plasma phase reactions due to its electro negative nature (i.e. it attracts bonding electrons and can quench the plasma state).

The arrangement such as that shown in FIG. 1 can improve the efficiency of the abatement process as this limits the abatement reaction within the hotter zone 6 to those related to the breakdown of C-F, S-F and F-F bindings and the reducing reactants converting F species into HF. The arrangement shown in FIG. 1 also helps to reduce the likelihood of oxygen-rich reactants reacting with N₂ radicals at higher temperatures. By introducing the oxygen-rich reactants in the lower temperature zone 7, this results in lower amounts of NOx.

To illustrate this, FIG. 5A shows thermal equilibrium simulations of a mixture of CF₄ and N₂ (at concentrations of 1% and 99% respectively). The injection of different reagents has a stoichiometry to maximize the destruction and removal efficiency (DRE) of CF₄. One abatement route for CF₄ is its oxidisation into COF₂. This is shown in FIG. 5A through the injection of just O₂ into the hot zone 6 of the plasma stream 6. The COF₂ is then hydrolysed into HF in the cold wet part of the abatement apparatus (not shown). As can be seen in FIG. 5B, the efficiency of the abatement can be improved if, rather than injecting O₂ into the hot zone 6, instead just H₂O is injected. As can be seen, this converts CF₄ more easily into HF and CO₂. However, as can be seen in FIG. 5B, there might be an attendant increase in NOx emissions versus the result shown in FIG. 5A, despite the lower power and temperature needed to abate CF₄. This is possibly due to the more favourable routes of NOx creation where H₂O radicals are present with N₂ radicals as shown by the NO value constant increment versus temperature in FIG. 5B. As can be seen in both FIGS. 5A and 5B, just injecting O₂ or just injecting H₂O into the plasma stream 6 leads to unwanted by-products as well as undesirable levels of NOx.

However, as can be seen in FIGS. 5C and 5D, by splitting the addition of the reactants using the arrangement shown in FIG. 1, the abatement performance is improved significantly. As can be seen, if CF₄ is reacted firstly with H₂ in the hotter zone 6 and then with O₂ in the cooler zone 7, an abatement may be achieved ideally with very few by-products such as CO and NOx, as shown in FIGS. 5C and 5B respectively. It is worth noting that the O₂ simulations in FIG. 5D refer to O₂ high temperature reactions with the by-products of the first reaction with hydrogen shown in FIG. 5C. This O₂ step is required to oxidize some C_{X}H_{Y}N_{Z} by-products into less harmful compounds.

FIG. 5E shows that the concurrent injection of H₂ and O₂ does not provide the same results as the two-step abatement process illustrated in FIGS. 5C and 5D since, as can be seen, significant amounts of NOx and other unwanted by-products can still be generated.

Other Arrangements

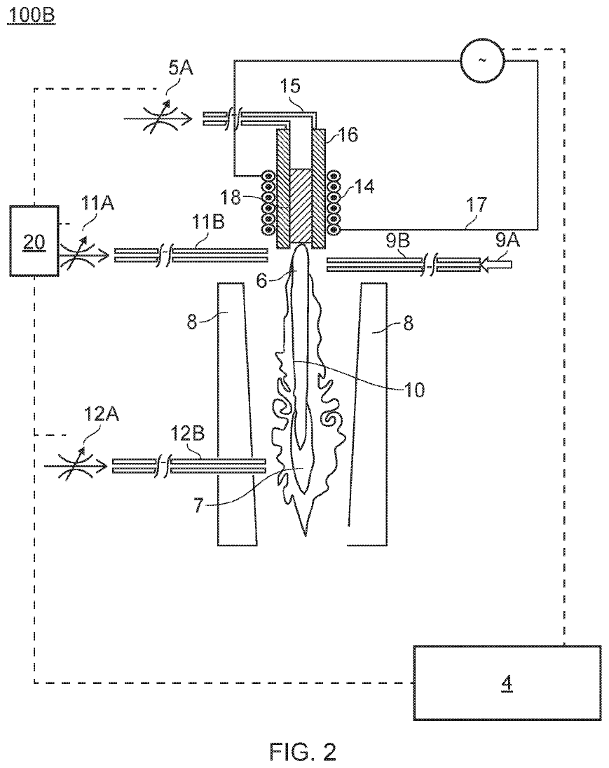

FIG. 2 shows an arrangement similar to that of FIG. 1 but which utilizes an inductively coupled plasma torch 1008. In this arrangement, the plasma plume 10 is generated by ionizing the plasma gas carrier 5A which is injected into an insulated tube 16 via a plasma gas carrier conduit 15. Electromagnetic energy to sustain the discharge is supplied via a radio frequency power supply 13 coupled through coils 14. A matching box 17 is provided to match the load provided by the gas discharge 18.

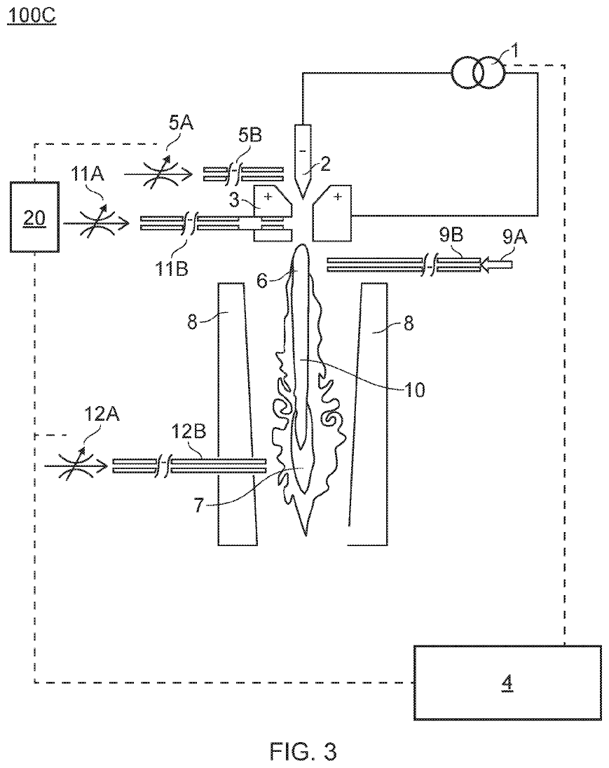

FIG. 3 is similar to that shown in FIG. 1 but the reducing reactant 11A is introduced inside or in close proximity to the cathode 2 so that it mixes with the plasma gas carrier 5A to maximize its ionization and effectiveness as a reactant. A further advantage of this arrangement is that NH₃ may be generated when N₂ is employed as a plasma gas and this can reduce the baseline amount of NOx emission from the plasma torch 100C (such as when the effluent stream 9A does not include any compounds other than a purge compound).

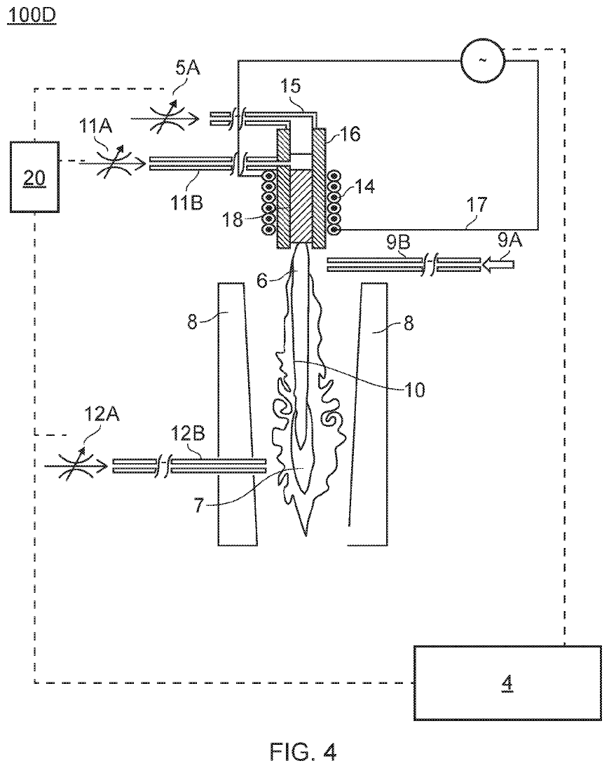

FIG. 4 shows an arrangement which is similar to that shown in FIG. 2 but with the reducing reagent 11A being injected inside or in close proximity to the gas discharge 18 of the insulated tube 16 of the plasma torch 100D to provide similar advantages to those described with reference to FIG. 3 above.

Although in this example hydrogen is used as the reducing agent, it will be appreciated that other reducing agents such as an alkaline earth metal such as beryllium, magnesium, calcium, strontium, barium and the like and/or an alkaline earth salt may be used. Additionally, other reducing agents such as NH₃, and/or a hydrocarbon such as propane, methane and the like may be used. As mentioned above, the NH₃ may be generated by thermal decomposition of an ammonia salt such as ammonium carbonate (NH₄)2CO₃, or the like either within the first region 6 or in-situ by the generating device 20. Similarly, the hydrogen may be generated in-situ through electrolysis by the generating device 20.

Likewise, although in this example oxygen is used as the oxidizing reactant, it will be appreciated that other oxidizing reactants such as ozone.

Also, although the reducing reactant is shown being introduced between the anode 3 and the reaction chamber 8, it will be appreciated that this need not be the case and that the reducing reactant simply needs to be introduced at a location where the plasma stream is hotter than the location where the oxidizing reactant is introduced.

Additionally, although the embodiments have been described with reference to a DC plasma torch and an inductively coupled plasma torch, it will be appreciated that the same approach can be used for other plasma devices and sources of plasma such as, for example, a microwave plasma discharge.

Some embodiments address the optimization of thermal plasma abatement with the aim of reducing thermal NOx generation and increasing abatement reaction efficiency. Looking at thermal equilibrium simulations, it has become apparent that the abatement reactions involving the reduction of fluorinated species, F₂, CFx and SFy into HF require much higher temperatures of the oxidation reaction of other abatement byproducts such as CO and CxHy. Some embodiments involve a thermal plasma abatement in two steps: 1) a hydrogen-rich reagent is injected in a much hotter reaction zone or premixed with torch plasma gas 2) the oxygen-rich reagents are injected further downstream in a relatively less hot zone. This provides for a split injection of two kinds of reagents in thermal plasma abatement.

Although illustrative embodiments of the invention have been disclosed in detail herein, with reference to the accompanying drawings, it is understood that the invention is not limited to the precise embodiment and that various changes and modifications can be effected therein by one skilled in the art without departing from the scope of the invention as defined by the appended claims and their equivalents.

### REFERENCE SIGNS

power supply 1; 13
anode 2
cathode 3
controller 4
plasma gas carrier 5A
plasma gas carrier conduit 5B; 15
hotter zone 6
cooler zone 7
reaction chamber 8
effluent stream 9A
effluent stream conduit 9B
plasma plume 10
reducing reactant 11A
reducing reactant conduit 11B
oxidising reactant 12A
oxidising reactant conduit 12B
coils 14
insulated tube 16
matching box 17
generating device 20
plasma torch 100A; 100B; 100C; 100D

1. A plasma abatement apparatus for treating an effluent stream from a semiconductor processing tool, said plasma abatement apparatus comprising:
a plasma device configured to generate a plasma stream from a plasma gas;
an effluent stream aperture configured to convey said effluent stream into said plasma stream for treatment by said plasma stream;
a first aperture positioned to deliver a reducing reactant to a first region of said plasma stream; and
a second aperture positioned to deliver an oxidising reactant to a second region of said plasma stream, wherein said second region is located at a position of said plasma stream which is cooler than said first region.

2. The apparatus of claim 1, wherein said first region is located at a position of said plasma stream which is hotter than said second region.

3. The apparatus of claim 1, wherein said first region is located at a position of said plasma stream which achieves a temperature of at least 1000° C.

4. The apparatus of claim 1, wherein said second region is located at a position of said plasma stream which achieves a temperature of no more than 1000° C.

5. The apparatus of claim 1, wherein said second region is located at a position of said plasma stream which achieves a temperature of at least 500° C.

6. The apparatus of claim 1, wherein said second region is located downstream of said first region.

7. The apparatus of claim 1, wherein said first region is located upstream of said second region.

8. The apparatus of claim 1, wherein said reducing reactant is premixed with said plasma gas prior to delivery to said plasma device.

9. The apparatus of claim 1, wherein said first region is located proximate said plasma device.

10. The apparatus of claim 1, said second region is located distal said plasma device.

11. The apparatus of claim 1, comprising a reaction chamber positioned to receive said plasma stream and wherein said second region is located within said reaction chamber.

12. The apparatus of claim 1, wherein said reducing reactant comprises at least one of:
H₂,
NH₃,
a hydrocarbon such as propane, methane and the like,
an alkaline earth metal such as beryllium, magnesium, calcium, strontium, barium,
an alkaline earth salt
an alkaline metal such as lithium, sodium, potassium, rubidium and
an alkaline salt.

13. The apparatus of claim 12, comprising:
a hydrogen generator configured to generate said H₂ in situ by electrolysis.

14. The apparatus of claim 12, comprising at least one of:
a power generator employed to generate said plasma stream; and
a secondary power source configured to power said hydrogen generator.

15. The apparatus of claim 12, wherein said first aperture is configured to deliver an ammonia salt such as ammonium carbonate (NH₄)2CO₃, or the like to generate said NH₃ by thermal decomposition within said first region.

16. The apparatus of claim 12, comprising:
a heater configured to generate said NH₃ by thermal decomposition of an ammonia salt such as ammonium carbonate (NH₄)2CO₃, or the like.

17. The apparatus of claim 1, wherein said oxidising reactant comprises at least one of O₂ and O₃.

18. A method of treating an effluent stream from a semiconductor processing tool, comprising:
generating a plasma stream from a plasma gas;
conveying said effluent stream into said plasma stream for treatment by said plasma stream;
delivering a reducing reactant to a first region of said plasma stream; and
delivering an oxidising reactant to a second region of said plasma stream which is located at a position of said plasma stream which is cooler than said first region.
